(19) United States
(12) Patent Application Publication
(10) Pub. No.: US 2005/0258518 A1
(43) Pub. Date: Nov. 24, 2005

(54) Image sensor package module with a leadless leadframe between chips

(75) Inventors: Jun-Young Yang, Kaohsiung (TW); You-Ock Joo, Kaohsiung (TW); Kwan-Yong Chung, Kaohsiung (TW)

Correspondence Address: TROXELL LAW OFFICE PLLC;SUITE 1404, 5205 LEESBURG PIKE, FALLS CHURCH, VA, 22041, US

(73) Assignee: Advanced Semiconductor Engineering Inc.

(21) Appl. No.: 10/851,170

(22) Filed: May 24, 2004

(51) Int. Cl. H01L 23/02

(52) U.S. Cl. 257/666

(57) ABSTRACT

An image sensor package module with a leadless leadframe between chips includes a chip carrier, an image sensor chip, an integrated circuit chip, and a flexible printed circuit board. The chip carrier comprises a leadless leadframe and a pre-molded body. The leadless leadframe has a plurality of leads. The pre-molded body is completely filled among the leads and has a dam on the upper surfaces of the leads. The upper surfaces and lower surfaces of the leads are exposed on the pre-molded body. The image sensor chip is attached to the chip carrier inside the dam and electrically connected to the upper surfaces of the leads. The integrated circuit chip is mounted on the lower surfaces of the leads via bumps. The flexible printed circuit board is electrically connected to the leads for signal transmission.

### FIELD OF THE INVENTION

The present invention relates to a CMOS image sensor module, more particularly, an image sensor package module with a leadless leadframe between chips.

### BACKGROUND OF THE INVENTION

CMOS image sensor chips can be integrated with other integrated circuits in a package module to reduce the footprint of the final packages and lower the cost of packaging. A conventional multi-chip CMOS image sensor package module is revealed in R.O.C. Taiwan Pat. No. 556,965. As shown in FIG. 1, the multi-chip CMOS image sensor package module includes an image sensor package 10 and an integrated circuit chip 20. The image sensor package 10 has a printed circuit frame, i.e., a laminated substrate 11. A dam wall 12 is formed on the upper surface 11a of the laminated substrate 11. An image sensor chip 13 is attached to the laminated substrate 11 inside the wall 12. The image sensor chip 13 is electrically connected to the upper surface 11a of the laminated substrate 11 by a plurality of bonding wires 14. A transparent glass 15 is attached to the top of the wall 12 to seal the image sensor chip 13. Moreover, the integrated circuit chip 20 is mounted on the lower surface 11b of the laminated substrate 11 which is electrically connected to the lower surface 11b of the laminated substrate 11 by a plurality of solder bumps. A plurality of solder balls 30 are placed on the lower surface 11b of the laminated substrate 11 to connect the signal of the multi-chip CMOS image sensor module to an exterior PCB board, not shown in the figure. However, because the raw material of the laminated substrate 11 is made of glass-fiber composite resin, FR-4, FR-5 or Bismaleimide Triazine (BT), the cost for the laminated substrate 11 is high and cannot meet the market demand of lower cost. Also, the moisture resistance of the laminated substrate 11 is bad. Moreover, due to the heat generated by the operation of image sensor chip package 13 and the integrated circuit package 20, the laminated substrate 11 can be warpaged and deformed which ends up with product failure.

### SUMMARY OF THE INVENTION

A main purpose of the present invention is to provide an image sensor package module with a leadless leadframe between chips. The image sensor package module includes a chip carrier, an image sensor chip, an integrated circuit chip such as DSP (digital signal processor) chip, and a flexible printed circuit board. The chip carrier comprises a leadless leadframe and a pre-molded body which completely fills among a plurality of leads of the leadless leadframe, and the pre-molded body has a dam on the upper surface of the leads. The upper surfaces and the lower surfaces of the leads have a plurality of connecting regions exposed out of the pre-molded body so that the image sensor chip and the integrated circuit chip can be electrically connected to the leadless leadframe. A lower packaging cost with highly integrated the image sensor chip with the DSP chip or other integrated circuits can be achieved.

According to the present invention, an image sensor package module with a leadless leadframe between chips includes a chip carrier, an image sensor chip, an integrated circuit chip, and a flexible printed circuit board. The chip carrier comprises a leadless leadframe and a pre-molded body. The leadless leadframe has a plurality of leads. Each lead has an upper surface and a lower surface. The pre-molded body is completely filled among the leads, and comprises a dam on the upper surfaces of the leads. The upper surfaces and the lower surfaces of the leads are exposed on the pre-molded body. The image sensor chip is attached to the leads or a chip pad of the chip carrier inside the dam, and electrically connected to the upper surface of the leads by a plurality of bonding wires. A transparent cover glass is attached to the dam of the pre-molded body to seal the image sensor chip. The integrated circuit chip has a plurality of solder bumps on its active surface for electrical connection to the lower surface of the leads of the leadless leadframe. The flexible printed circuit board is connected to the leads of the leadless leadframe for outer electrical connection.

### DESCRIPTION OF THE DRAWINGS

FIG. 1 is a cross-sectional view of a well-known multi-chip CMOS image sensor module.

FIG. 2 is a cross-sectional view of an image sensor package module with leadframe between chips configuration in accordance with the first embodiment of the present invention.

FIG. 3 is a bottom view of the image sensor package module in accordance with the first embodiment of the present invention.

FIG. 4 is a cross-sectional view of an image sensor package module with leadframe between chips configuration in accordance with the second embodiment of the present invention.

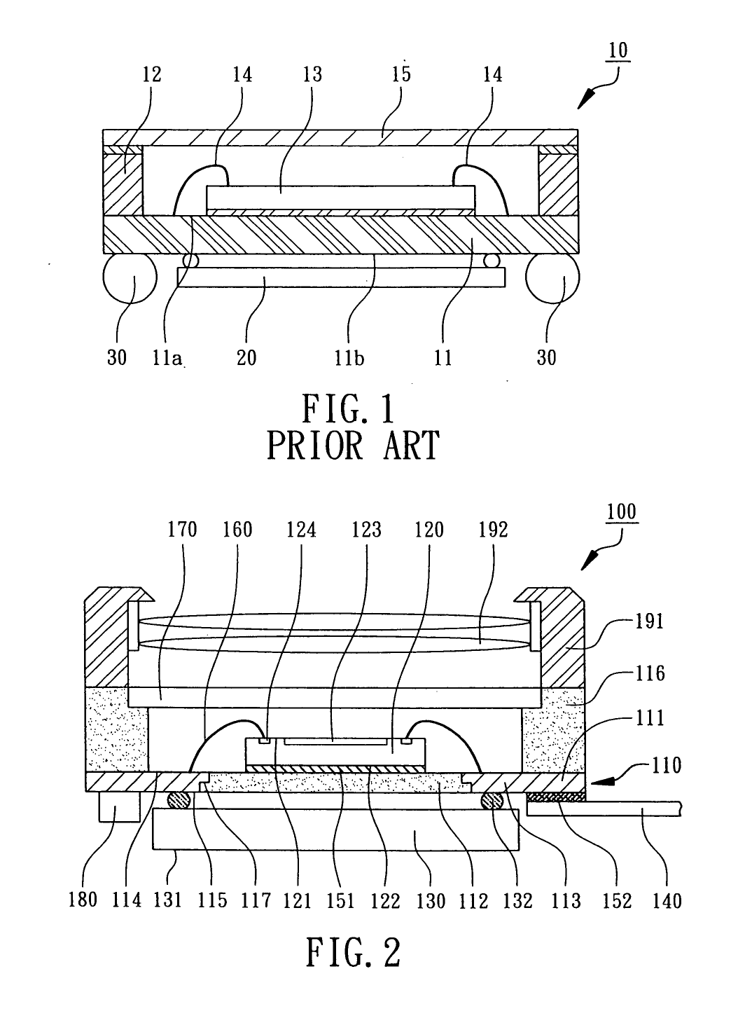

### DETAIL DESCRIPTION OF THE INVENTION

Please refer to the drawings attached, the present invention will be described by means of an embodiment below.

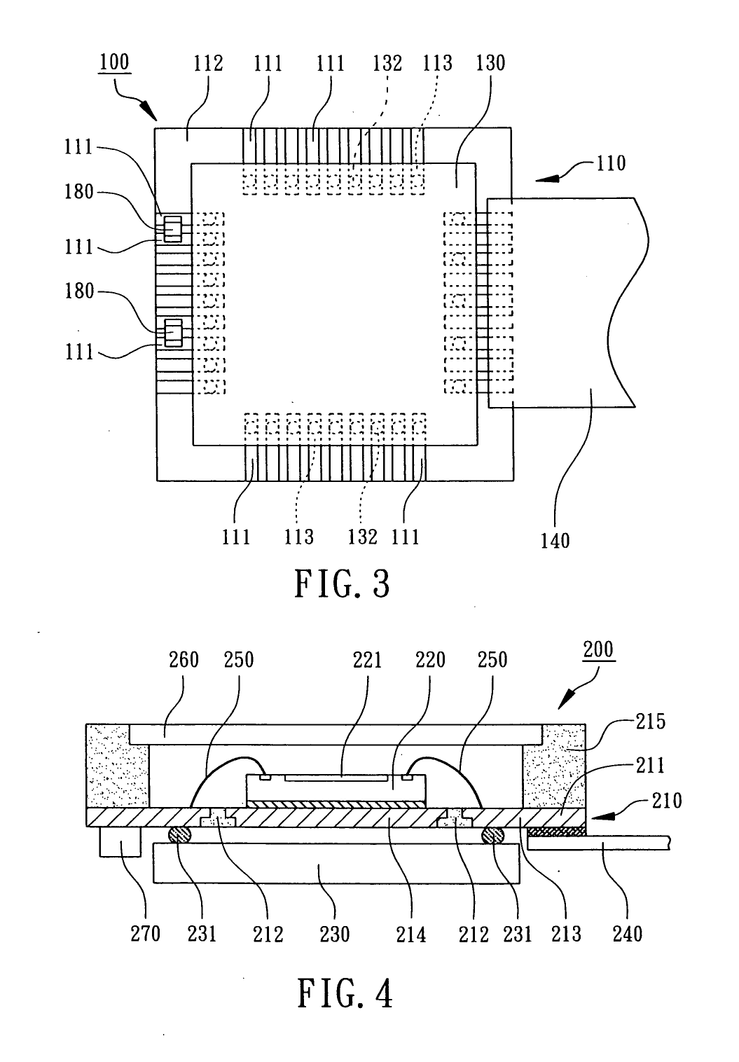

According to the present invention, as shown in FIGS. 2 and 3, an image sensor package module 100 with a leadframe between chips configuration comprises a chip carrier 110, an image sensor chip 120, an integrated circuit chip 130 and a flexible printed circuit board 140. The chip carrier 110 includes a leadless leadframe 111 and a pre-molded body 112. The leadless leadframe includes a plurality of leads 113. Each lead 113 has an upper surface 114 and a lower surface 115. Moreover, the pre-molded body 112 is completely filled between the leads 113 and has a circular dam 116 on the upper surface 114 of the leads 113. The upper surface 113 and the lower surface 114 of the leads 113 respectively have a plurality of connecting regions exposed out of the pre-molded body 112. Preferably, the leads 113 have a plurality of pre-molded lock portions 117, for example half-etching portions, to enhance the bonding strength with the pre-molded body 112.

The image sensor chip 120 may be a charge-coupled device, CCD or a complementary metal-oxide-semiconductor, CMOS. The image sensor chip 120 has an active surface 121 and a backside surface 122. The active surface 121 includes a sensing region 123, and a plurality of bonding pads 124 are formed at periphery of the active surface 121. The image sensor chip 120 is mounted inside the circular dam 116 of the chip carrier 110 by using a die attach material 151 bonding the backside surface 122 on the chip carrier 110. In this embodiment, the image sensor chip 120 is attached to the pre-molded body 112. The bonding pads 124 of the image sensor chip 120 electrically connect to the upper surfaces 114 of the leads 113 by a plurality of bonding wires 160. A transparent cover 170 is attached to the circular dam 116 of the pre-molded body 112 to seal the image sensor chip 120. The transparent cover 170 may be an IR-cut filter. The integrated circuit chip 130 may be a CSP (chip scale package) or a flip chip, which has a mounting surface 131 on which a plurality of solder bumps 132 or the other bumps are formed. In this embodiment, the integrated circuit chip 130 is a DSP chip (digital signal processor). The solder bumps 132 are bonded to the lower surfaces 115 (connecting regions) of the leads 113 so that the integrated circuit chip 130 can be electrically connected to the leadless leadframe 111, preferably, at least a passive component 180 is mounted on the lower surface 115 of the leads 113. The flexible printed circuit board 140 is electrically connected to the leads 113 by an anisotropic conductive paste 152 (ACP) to transmit the signal of the image sensor package module 100 to the outside world.

In the present invention, the image sensor package module 100 also comprises a lens holder 191 and a lens 192. The lens 192 is supported by the lens holder 191. The lens holder 191 is connected with the circular dam 116 of the pre-molded body 112 so that the lens 192 is aligned to the sensing region 123 of the image sensor chip 120. The image sensor chip 120 is attached on the chip carrier 110 inside the circular dam 116 of the pre-molded body 112 and electrically connected to the upper surface 114 of the leads 113. Moreover, the integrated circuit chip 130 is mounted on the lower surface 115 of the lead 113. Through the internal circuit design, the signal input of the integrated circuit chip 130 can be connected with the signal output of the image sensor chip 120 by inner-connecting lead(s) 113. Moreover, the signal outputs of the integrated circuit chip 130 are connected to the flexible printed circuit board 140 by outer-connecting lead(s) 113. Therefore, the signal of the image sensor chip 120 will transmit to integrated circuit chip 130 for digital signal processing, then transmit the processed signals to outer electrical device through the flexible printed circuit board 140. The image sensor chip 120 and integrated circuit chip 130 can be highly integrated to reduce the overall packaging cost.

Referring to FIG. 4, an image sensor package module 200 is illuminated in second embodiment. The image sensor package module 200 includes a chip carrier 210, a image sensor chip 220, an integrated circuit chip 230 and a flexible printed circuit board 240. The chip carrier 210 includes a leadless leadframe 211 and a pre-molded body 212. In this embodiment, the leadless leadframe 211 has a plurality of leads 213 and a chip pad 214, the pre-molded body 212 is filled between the chip pad 214 and the leads 213. The pre-molded body 212 has a dam 215 on the upper surfaces of the leads to accommodate the image sensor chip 220. The image sensor chip 220 is attached to the chip pad 214 on the upper surface of the chip carrier 210 inside the dam 215 and electrically connected to the upper surfaces of the leads 213 via a plurality of bonding wires 250. The sensing region 221 of the image sensor chip 220 is oriented to the opening of the dam 215. A transparent cover 260 is attached to the dam 215 to seal the image sensor chip 220. The integrated circuit chip 230 is flip-chip bonded to the lower surface of the chip carrier 210 to connect the leads 213 via a plurality of bumps 231. The flexible printed circuit board 240 is also connected to the lower surfaces of the leads 213 for outer connection. At least a passive component 270 can be mounted to the chip carrier 210.

The above description of embodiments of this invention is intended to be illustrative and not limiting. Other embodiments of this invention will be obvious to those skilled in the art in view of the above disclosure.

1. An image sensor package module with a leadless leadframe between chips comprising:
a chip carrier including a leadless leadframe and a pre-molded body, wherein the leadless leadframe has a plurality of leads, each lead has an upper surface and a lower surface, the pre-molded body is filled between the leads and has a dam on the upper surfaces of the leads;
an image sensor chip attached to the chip carrier inside the dam;
a plurality of bonding wires electrically connecting the image sensor chip and the upper surfaces of the leads;
a transparent cover attached to the dam to seal the image sensor chip;
an integrated circuit chip having a mounting surface, wherein a plurality of bumps are formed on the mounting surface and connected to the lower surfaces of the leads; and
a flexible printed circuit board electrically connecting to the leads.

2. The package module of claim 1, wherein the upper surfaces and the lower surfaces of the leads have a plurality of connecting regions exposed out of the pre-molded body for electrical connection of the image sensor chip and the integrated circuit chip.

3. The package module of claim 1, wherein the integrated circuit chip is a DSP chip (digital signal processor).

4. The package module of claim 1, wherein the dam is circular.

5. The package module of claim 1, wherein the image sensor chip is attached to the pre-molded body.

6. The package module of claim 1, wherein the leadless leadframe has a chip pad for attaching the image sensor chip, the pre-molded body is filled between the chip pad and the leads.

7. The package module of claim 1, further comprising at least a passive component connected to one of the leads.

8. The package module of claim 1, further comprising an anisotropic conductive paste for electrically connecting the flexible printed circuit board and the leads.

9. The package module of claim 1, further comprising a lens holder mounted on the dam.

10. The package module of claim 9, further comprising at least a lens supported by the lens holder.

11. The package module of claim 1, wherein the transparent cover is an IR-cut filter.

12. The package module of claim 1, wherein the integrated circuit chip is a chip scale package (CSP).

13. The package module of claim 1, wherein the leads have a plurality of pre-molded lock portions.

14. The package module of claim 13, wherein the pre-molded lock portions comprise half-etching portions.
